(19) United States
(12) Patent Application Publication
(10) Pub. No.: US 2026/0173986 A1
(43) Pub. Date: Jun. 18, 2026

(54) SEMICONDUCTOR PACKAGE SUPPRESSING ELECTRICAL COUPLING AND METHOD OF MAKING THE SAME

(71) Applicant: ALPHA AND OMEGA SEMICONDUCTOR INTERNATIONAL LP, TORONTO (CA)

(72) Inventors: Yan Xun Xue, Los Gatos, CA (US); Jian Yin, San Ramon, CA (US); Madhur Bobde, Sunnyvale, CA (US); Long-Ching Wang, Cupertino, CA (US); Kuan-Hung Li, Zhubei City (TW); Zhiqiang Niu, Santa Clara, CA (US)

(73) Assignee: ALPHA AND OMEGA SEMICONDUCTOR INTERNATIONAL LP, TORONTO, ON (CA)

(21) Appl. No.: 18/984,370

(22) Filed: Dec. 17, 2024

(51) Int. Cl. H01L 23/495

(52) U.S. Cl. CPC H10W 90/811; H10W 70/417; H10W 70/465

(57) ABSTRACT

A semiconductor package comprises a lead frame, a first high side field-effect transistor (FET), a second high side FET, a first metal clip, a second metal clip, a first low side FET, a second low side FET, a third metal clip, a metal slug, an integrated circuit (IC), a plurality of bond wires, and a molding encapsulation. A method comprises the steps of providing a lead frame; mounting a first high side FET and a second high side FET; attaching a first metal clip and a second metal clip; mounting a first low side FET and a second low side FET; attaching a third metal clip; attaching an IC; forming a molding encapsulation; and applying a singulation process.

### FIELD OF THE INVENTION

This invention relates generally to a semiconductor package and a method of making the same. More particularly, the present invention relates to the semiconductor package, suppressing electrical coupling and having stacked field-effect transistors (FETs) and an integrated circuit (IC) and the method of making the same.

### BACKGROUND OF THE INVENTION

Conventional dual driver metal-oxide-silicon field-effect transistor (DrMOSFET) includes stacked FETs thereby experiences electrical coupling issue.

The semiconductor package of the present disclosure includes a lower pair of metal clips, and an upper metal clip comprising two vertical legs connecting to a ground terminal thereby suppressing the electrical coupling.

### SUMMARY OF THE INVENTION

The present invention discloses a semiconductor package comprising a lead frame, a first high side FET, a second high side FET, a first metal clip, a second metal clip, a first low side FET, a second low side FET, a third metal clip, a metal slug, an IC, a plurality of bond wires, and a molding encapsulation.

A method for fabricating a semiconductor package is also disclosed. The method comprises the steps of providing a lead frame; mounting a first high side FET and a second high side FET; attaching a first metal clip and a second metal clip; mounting a first low side FET and a second low side FET; attaching a third metal clip; attaching an IC; forming a molding encapsulation; and applying a singulation process.

### BRIEF DESCRIPTION OF THE DRAWINGS

FIG. 1A is a top perspective view and FIG. 1B is a bottom perspective view of a semiconductor package in examples of the present disclosure.

FIG. 2 is a top perspective view of another semiconductor package in examples of the present disclosure.

FIG. 3 is a top perspective view of the semiconductor package of FIG. 1A, without showing the molding encapsulation, in examples of the present disclosure.

FIG. 4 is an exploded plot of the semiconductor package of FIG. 1A, without showing the molding encapsulation, in examples of the present disclosure.

FIG. 5 is a flowchart of a process to develop a semiconductor package in examples of the present disclosure.

FIGS. 6AA, 6BA, 6CA, 6DA, 6EA, 6EC, 6FA, 6GA, and 6HA show top views and FIGS. 6AB, 6BB, 6CB, 6DB, 6EB, 6ED, 6FB, 6GB, 6HB, and 6I show side views of the process of FIG. 5 to fabricate the semiconductor package in examples of the present disclosure.

### DETAILED DESCRIPTION OF THE INVENTION

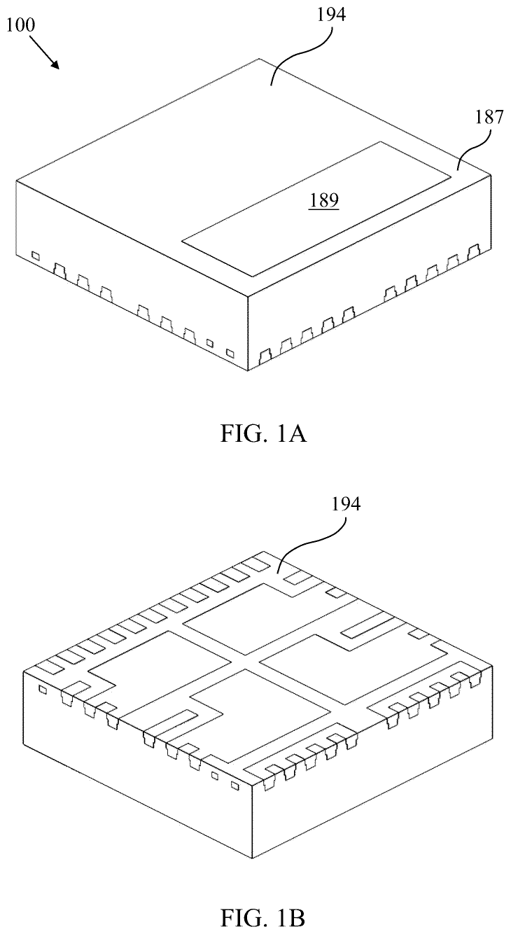

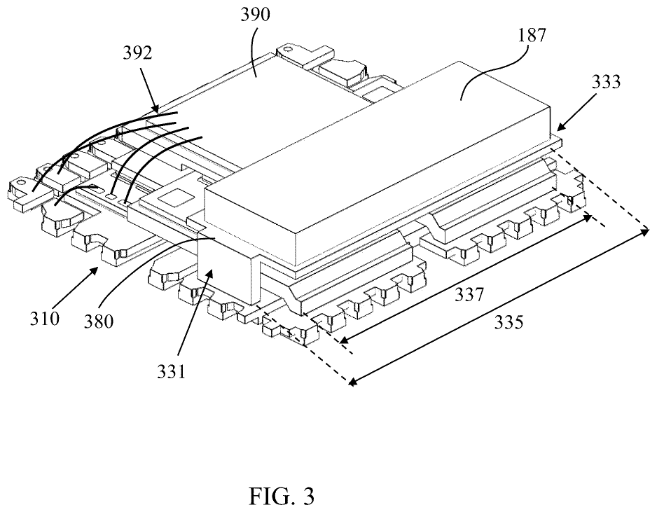

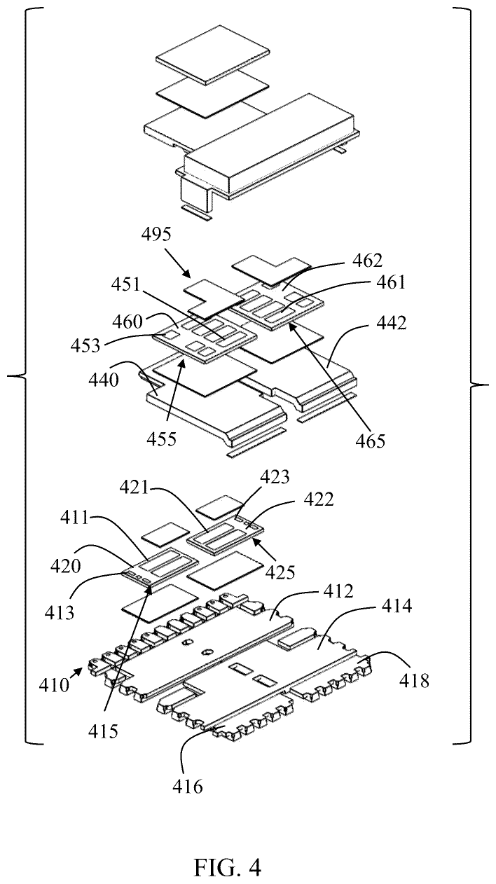

FIG. 1A is a top perspective view and FIG. 1B is a bottom perspective view of a semiconductor package 100 in examples of the present disclosure. FIG. 3 is a top perspective view of the semiconductor package 100 of FIG. 1A, without showing the molding encapsulation, in examples of the present disclosure. FIG. 4 is an exploded plot of the semiconductor package 100 of FIG. 1A, without showing the molding encapsulation, in examples of the present disclosure. The semiconductor package 100 comprises a lead frame 310 of FIG. 3, a first high side FET 420 of FIG. 4, a second high side FET 422 of FIG. 4, a first metal clip 440 of FIG. 4, a second metal clip 442 of FIG. 4, a first low side FET 460 of FIG. 4, a second low side FET 462 of FIG. 4, a third metal clip 380 of FIG. 3, a metal slug 187 of FIG. 1A and FIG. 3, an IC 390 of FIG. 3, a plurality of bond wires 392 of FIG. 3, and a molding encapsulation 194 of FIG. 1A and FIG. 1B.

In examples of the present disclosure, the semiconductor package 100 is a dual driver metal-oxide-silicon field-effect transistor (DrMOSFET). In other examples of the present disclosure, the semiconductor package 100 is a dual phase power stage excluding the IC 390.

In examples of the present disclosure, the semiconductor package 100 is of a first rectangular prism shape. The first high side FET 420 and the second high side FET 422 are of a second rectangular prism shape. The first low side FET 460 and the second low side FET 462 are of a third rectangular prism shape. The metal slug 187 is of a fourth rectangular prism shape. An outer profile of a bottom surface of the lead frame 310 is of a rectangular shape. As shown, the first high side FET 420 and the second high side FET 422 are formed on two different semiconductor chips. Alternatively, the first high side FET 420 and the second high side FET 422 are formed on a same semiconductor chip as common drain FETs (not shown).

The lead frame 310 of FIG. 3 comprises a die paddle 412 of FIG. 4, a common ground paddle 414 of FIG. 4, a first phase node lead 416 of FIG. 4, and a second phase node lead 418 of FIG. 4. In examples of the present disclosure, the die paddle 412 of FIG. 4 is connected to a power source (Vin) terminal. The common ground paddle 414 of FIG. 4 is connected to a ground (PGND) terminal. As shown, the die paddle 412 has substantially a rectangular shape with a plurality of leads 410 disposed on a first longitudinal side of the die paddle 412. The common ground paddle 414 disposed on a second longitudinal side opposite the first longitudinal side of the die paddle 412 extends an entire longitudinal length of the die paddle 412. The first phase node lead 416 and the second phase node lead 418 disposed on the second longitudinal side of the die paddle 412 are separated from the die paddle 412 with the common ground paddle 414 therebetween.

The first high side FET 420 of FIG. 4 is attached to the die paddle 412 of FIG. 4. The first high side FET 420 of FIG. 4 comprises a source electrode 411 and a gate electrode 413 on a front surface of the first high side FET 420; and a drain electrode 415 on a back surface of the first high side FET 420. The drain electrode 415 of the first high side FET 420 is electrically connected to the die paddle 412.

The second high side FET 422 of FIG. 4 is attached to the die paddle 412 of FIG. 4. The second high side FET 422 of FIG. 4 comprises a source electrode 421 and a gate electrode 423 on a front surface of the second high side FET 422; and a drain electrode 425 on a back surface of the second high side FET 422. The drain electrode 425 of the second high side FET 422 is electrically connected to the die paddle 412.

The first metal clip 440 on top of the first high side FET 420 connects the source electrode 411 of the first high side FET 420 to the first phase node lead 416. The second metal clip 442 on top of the second high side FET 422 connects the source electrode 421 of the second high side FET 422 to the second phase node lead 418.

The first low side FET 460 is attached to the first metal clip 440 on top of the first metal clip 440. The first low side FET 460 comprises a source electrode 451 and a gate electrode 453 on a front surface of the first low side FET 460; and a drain electrode 455 on a back surface of the first low side FET 460. The drain electrode 455 of the first low side FET 460 is electrically connected to the first metal clip 440.

The second low side FET 462 is attached to the second metal clip 442 on top of the second metal clip 442. The second low side FET 462 comprises a source electrode 461 and a gate electrode on a front surface of the second low side FET 462; and a drain electrode 465 on a back surface of the second low side FET 462. The drain electrode 465 of the second low side FET 462 is electrically connected to the second metal clip 442.

The third metal clip 380 connects the source electrode 451 of the first low side FET 460 and the source electrode 461 of the second low side FET 462 to the common ground paddle 414. In one example, the IC 390 is attached to a first area of the third metal clip 380 on top of the first area of the third metal clip 380. In another example, the IC 390 is not included in the package.

In examples of the present disclosure, the third metal clip 380 comprises a first vertical leg 331 of FIG. 3 attached to the common ground paddle 414; and a second vertical leg 333 of FIG. 3 attached to the common ground paddle 414. A distance 335 of FIG. 3 between a distal end surface of the first vertical leg 331 and a distal end surface of the second vertical leg 333 is greater than a distance 337 of FIG. 3 between a distal end surface of the first metal clip 440 and a distal end surface of the second metal clip 442.

The molding encapsulation 194 encloses the first high side FET 420, the second high side FET 422, the first metal clip 440, the second metal clip 442, the first low side FET 460, the second low side FET 462, the IC 390, a majority portion of the lead frame 310, and at least a majority portion of the third metal clip 380.

In examples of the present disclosure, the semiconductor package 100 further comprises a plurality of solder layers 495 of FIG. 4. The molding encapsulation 194 enclosed the plurality of solder layers 495.

In one example, the metal slug 187 is attached to the third metal clip 380. A top surface 189 of FIG. 1A of the metal slug 187 is exposed from the molding encapsulation 194. The metal slug 187 and the third metal clip 380 may be two separate pieces joined by solder or other adhesive. Alternatively, the metal slug 187 and the third metal clip 380 may be a single-piece construction (formed at a same time in a single process step).

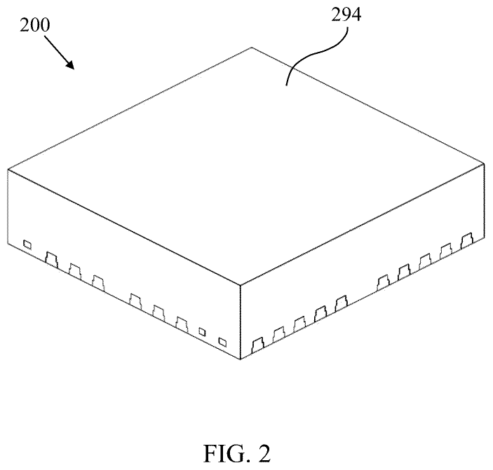

In another example, referring now to FIG. 2, a semiconductor package 200 excludes the metal slug 187 of FIG. 1A so that no exposed metal surface on a top surface of a molding encapsulation 294. The semiconductor package 200 is similar to the semiconductor package 100 of FIG. 1A except that the semiconductor package 200 excludes the metal slug 187. The molding encapsulation 194 enclosed an entirety of the third metal clip 380. In yet another example, the semiconductor package 200 further excludes the IC 390 in the package and the semiconductor package 200 is a dual phase power stage.

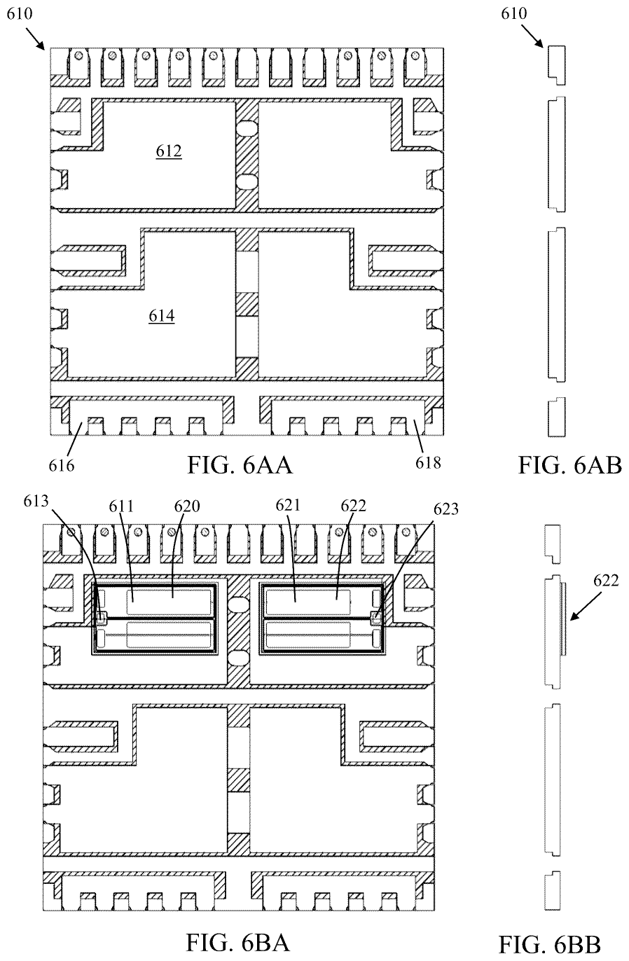

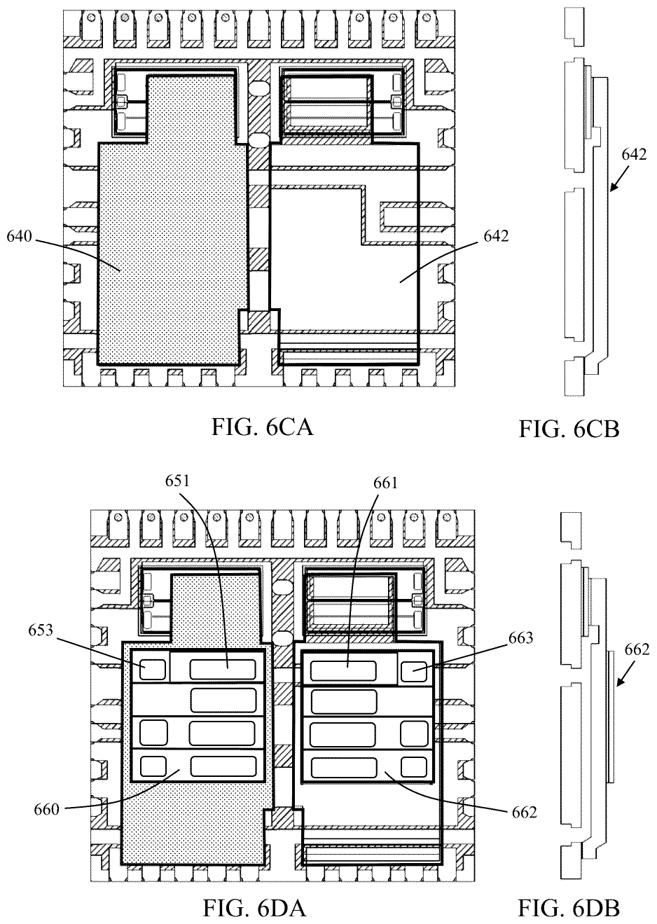

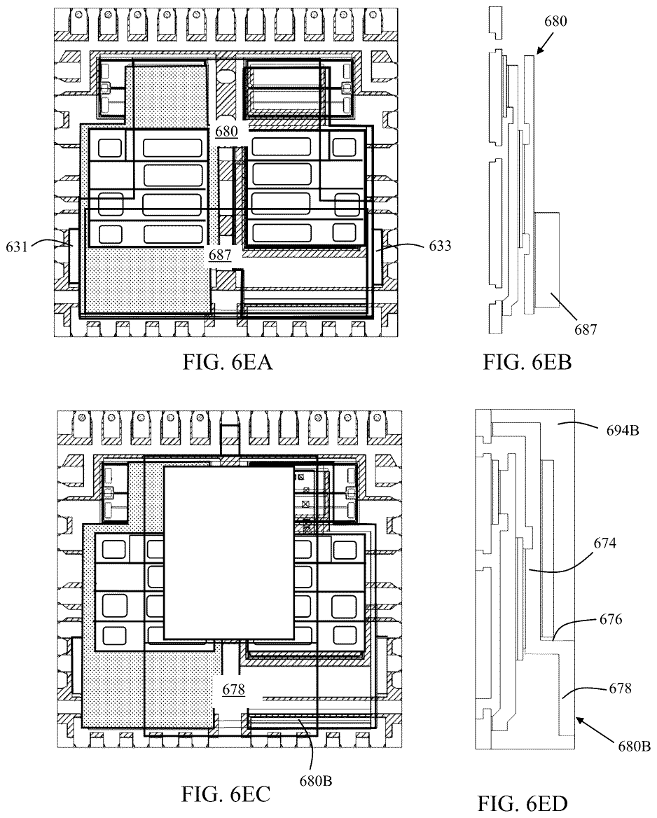

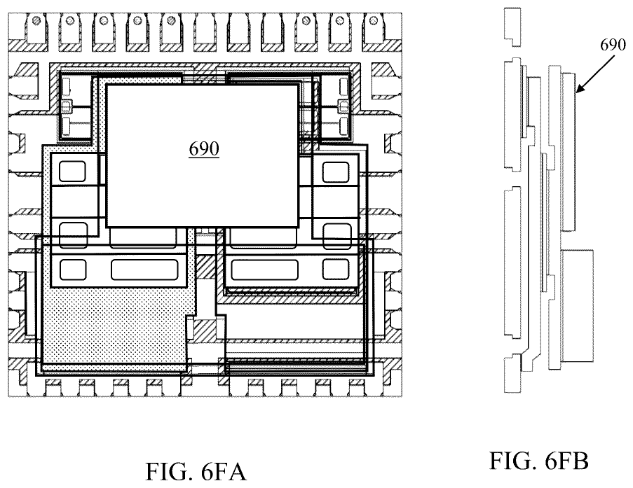

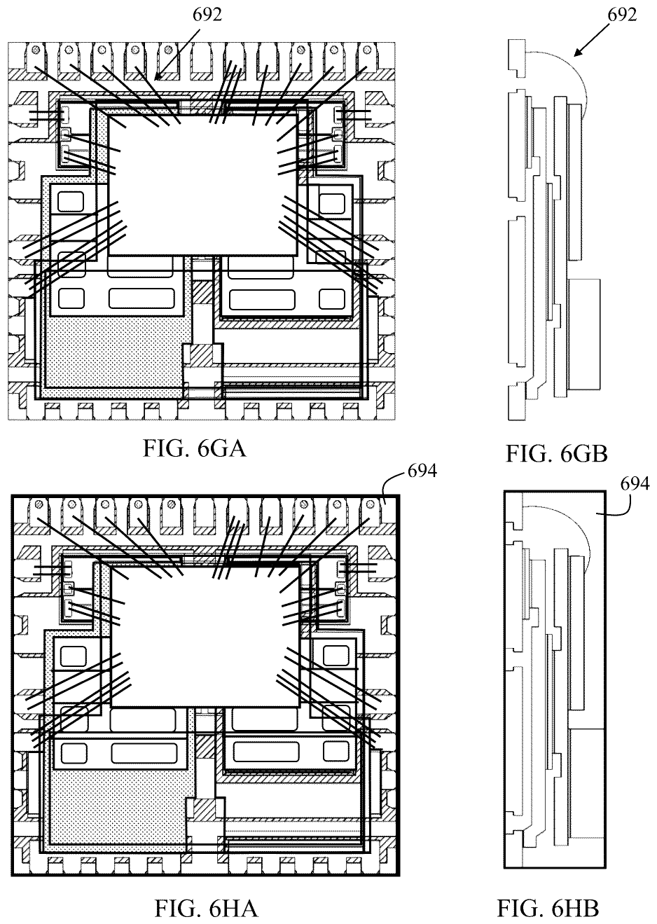

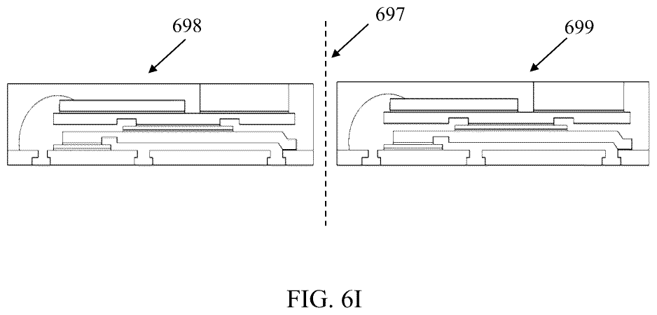

In still another example, referring now to FIG. 6EC and 6ED, a third metal clip 680B comprises a lower portion 674 and an upper portion 678 connected by a transition portion 676. A top surface of the upper portion 678 of the third metal clip 680B is exposed from the molding encapsulation 694B. As shown, the lower portion 674 comprises a lower metal plate and the upper portion 678 comprises an upper metal plate parallel to the lower metal plate. The transition portion 676 comprises a vertical metal plate substantially vertical to the lower metal and the upper metal plate. In another example, the lower metal plate and the upper metal plate have the same thickness. In another example, the lower metal plate, the vertical metal plate and the upper metal plate have the same thickness.

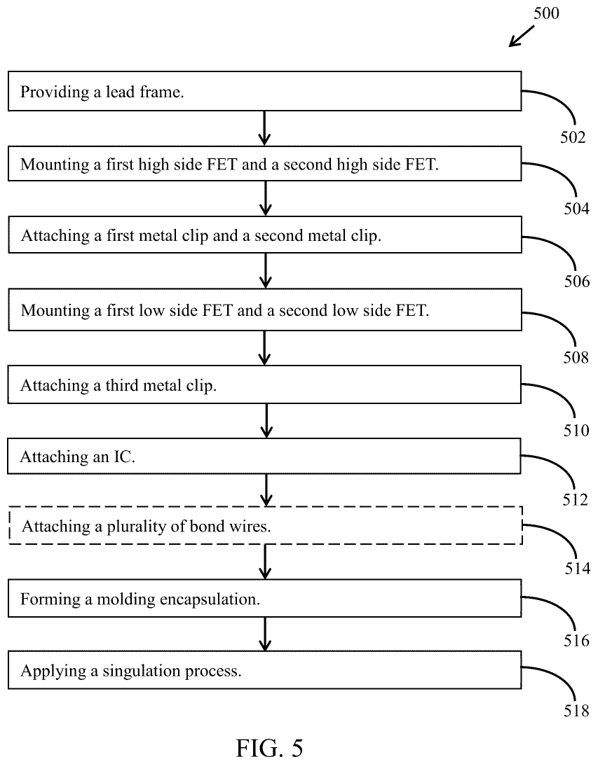

FIG. 5 is a flowchart of a process 500 to develop a semiconductor package in examples of the present disclosure. The process 500 may start from block 502. A plurality of semiconductor packages may be fabricated at the same time. In one example, FIG. 6I shows 2 semiconductor packages are fabricated at the same time. The number of semiconductor packages, fabricated at the same time, may vary. For simplicity, FIG. 6AA-6HB show the process steps for fabricating a single semiconductor package.

In block 502, referring now to FIG. 6AA and 6AB, a lead frame 610 is provided. The lead frame 610 comprises a die paddle 612, a common ground paddle 614, a first phase node lead 616, and a second phase node lead 618. In examples of the present disclosure, the die paddle 612 is connected to a power source (Vin) terminal. The common ground paddle 614 is connected to a ground (PGND) terminal. Block 502 may be followed by block 504.

In block 504, referring now to FIG. 6BA and 6BB, a first high side FET 620 and a second high side FET 622 are mounted. The first high side FET 620 of FIG. 4 is attached to the die paddle 612. The first high side FET 620 comprises a source electrode 611 and a gate electrode 613 on a front surface of the first high side FET 620; and a drain electrode on a back surface of the first high side FET 620. The drain electrode of the first high side FET 620 is electrically connected to the die paddle 612. The second high side FET 622 is attached to the die paddle 612. The second high side FET 622 comprises a source electrode 621 and a gate electrode 623 on a front surface of the second high side FET 622; and a drain electrode on a back surface of the second high side FET 622. The drain electrode of the second high side FET 622 is electrically connected to the die paddle 612. Block 504 may be followed by block 506.

In block 506, referring now to FIG. 6CA and 6CB, a first metal clip 640 and a second metal clip 642 are attached. The first metal clip 640 connects the source electrode 611 of the first high side FET 620 to the first phase node lead 616. The gate electrode 613 of the first high side FET 620 exposed from the first metal clip 640. The second metal clip 642 connects the source electrode 621 of the second high side FET 622 to the second phase node lead 618. The gate electrode 623 of the second high side FET 622 exposed from the second metal clip 642. Block 506 may be followed by block 508.

In block 508, referring now to FIG. 6DA and 6 DB, a first low side FET 660 and a second low side FET 662 are mounted. The first low side FET 660 is attached to the first metal clip 640. The first low side FET 660 comprises a source electrode 651 and a gate electrode 653 on a front surface of the first low side FET 660; and a drain electrode on a back surface of the first low side FET 660. The second low side FET 662 is attached to the second metal clip 642. The second low side FET 662 comprises a source electrode 661 and a gate electrode 663 on a front surface of the second low side FET 662; and a drain electrode on a back surface of the second low side FET 662. In examples of the present disclosure, the first low side FET 660 is mounted on the first metal clip 640 at a horizontal position shifted away from the first high side FET 620 and the second low side FET 662 is mounted on the second metal clip 642 at a horizontal position shifted away from the second high side FET 622. Block 508 may be followed by block 510.

In block 510, referring now to FIG. 6EA, 6EB, and 6EC, a third metal clip 680 is attached. The third metal clip 680 connects the source electrode 451 of the first low side FET 660 and the source electrode 461 of the second low side FET 462 to the common ground paddle 614. The gate electrode 653 of the first low side FET 660 and the gate electrode 663 of the second low side FET 662 expose from the third metal clip 680.

In examples of the present disclosure, the third metal clip 680 comprises a first vertical leg 631 attached to the common ground paddle 614; and a second vertical leg 633 attached to the common ground paddle 614. A distance 335 of FIG. 3 between a distal end surface of the first vertical leg 331 and a distal end surface of the second vertical leg 333 is greater than a distance 337 of FIG. 3 between a distal end surface of the first metal clip 440 and a distal end surface of the second metal clip 442.

In one example, a metal slug 687 is attached to the third metal clip 680. The metal slug 687 is disposed on the third metal clip 680 at a horizontal position at least overlapping a portion of the first low side FET 660 and the second low side FET 662. A top surface of the metal slug 687 is exposed from the molding encapsulation 694 of FIG. 6HB. The metal slug 687 and the third metal clip 680 may be two separate pieces before integration. Alternatively, the metal slug 687 and the third metal clip 680 may be a single-piece construction (formed at a same time in a single process step).

In another example, referring now to FIG. 2, a semiconductor package 200 excludes the metal slug 187 of FIG. 1A so that no exposed metal surface on a top surface of a molding encapsulation 294. The semiconductor package 200 is similar to the semiconductor package 100 of FIG. 1A except that the semiconductor package 200 excludes the metal slug 187. The molding encapsulation 194 enclosed an entirety of the third metal clip 380. In yet another example, the semiconductor package 200 further excludes the IC 390 in the package and the semiconductor package 200 is a dual phase power stage.

In still another example, referring now to FIG. 6EC and 6ED, a third metal clip 680B comprises a lower portion 674, a vertical portion 676, and an upper portion 678. A top surface of the upper portion 678 of the third metal clip 680B is exposed from the molding encapsulation 694B. Block 510 may be followed by block 512.

In block 512, referring now to FIG. 6FA and 6FB, an optional IC 690 is attached. The IC 690 is attached to the third metal clip 680 by a solder layer (one of the plurality of solder layers of FIG. 4). In one example, the IC 690 is mounted on the third metal clip 680 at a horizonal position overlapping the first high side FET 620 and/or the second high side FET 622. Block 512 may be followed by optional block 514 or block 516.

In block 514, referring now to FIG. 6GA and 6GB, a plurality of bond wires 692 are applied to connect the gate electrodes of the high side FETs and low side FETs to the IC 690. Operational block 514 may be followed by block 516.

In block 516, referring now to FIG. 6HA and 6HB, a molding encapsulation 694 is formed. The molding encapsulation 694 encloses the first high side FET 620, the second high side FET 622, the first metal clip 640, the second metal clip 642, the first low side FET 660, the second low side FET 662, the IC 690, a majority portion of the lead frame 610, and at least a majority portion of the third metal clip 680. Block 516 may be followed by block 518.

In block 518, referring now to FIG. 6I, a singulation process 697 is applied so as to separate the semiconductor package 698 from adjacent semiconductor packages 699. In examples of the present disclosure, the semiconductor package 698 and the adjacent semiconductor packages 699 are dual driver metal-oxide-silicon field-effect transistors (DrMOSFETs).

Those of ordinary skill in the art may recognize that modifications of the embodiments disclosed herein are possible. For example, a number of bond wires may vary. Other modifications may occur to those of ordinary skill in this art, and all such modifications are deemed to fall within the purview of the present invention, as defined by the claims.

1. A semiconductor package comprising:
a lead frame comprising:
a die paddle,
a common ground paddle,
a first phase node lead, and
a second phase node lead;
a first high side field-effect transistor (FET) attached to the die paddle, the first high side FET comprising:
a source electrode and a gate electrode on a front surface of the first high side FET; and
a drain electrode on a back surface of the first high side FET;
a second high side FET attached to the die paddle, the second high side FET comprising:
a source electrode and a gate electrode on a front surface of the second high side FET; and
a drain electrode on a back surface of the second high side FET;
a first metal clip connecting the drain electrode of the first high side FET to the first phase node lead;
a second metal clip connecting the drain electrode of the second high side FET to the second phase node lead;
a first low side FET attached to the first metal clip, the first low side FET comprising:
a source electrode and a gate electrode on a front surface of the first low side FET; and
a drain electrode on a back surface of the first low side FET;
a second low side FET attached to the second metal clip, the second low side FET comprising:
a source electrode and a gate electrode on a front surface of the second low side FET; and
a drain electrode on a back surface of the second low side FET;
a third metal clip connecting the source electrode of the first low side FET and the source electrode of the second low side FET to the common ground paddle; and
a molding encapsulation enclosing the first high side FET, the second high side FET, the first metal clip, the second metal clip, the first low side FET, the second low side FET, a majority portion of the lead frame, and at least a majority portion of the third metal clip.

2. The semiconductor package of claim 1 further comprising an integrated circuit (IC) attached to the third metal clip, wherein the molding encapsulation encloses the IC.

3. The semiconductor package of claim 2 further comprising a metal slug attached to the third metal clip;
wherein a top surface of the metal slug is exposed from the molding encapsulation.

4. The semiconductor package of claim 2, wherein the third metal clip comprises:
a lower portion; and
an upper portion;
wherein the IC attached to the lower portion of the third metal clip and wherein a top surface of the upper portion of the third metal clip is exposed from the molding encapsulation.

5. The semiconductor package of claim 2, wherein the first low side FET is mounted on the first metal clip at a horizontal position shifted away from the first high side FET; and
wherein the second low side FET is mounted on the second metal clip at a horizontal position shifted away from the second high side FET.

6. The semiconductor package of claim 5, the IC is mounted on the third metal clip at a horizonal position overlapping the first high side FET or the second high side FET.

7. The semiconductor package of claim 2, wherein the third metal clip comprises:
a first vertical leg attached to the common ground paddle; and
a second vertical leg attached to the common ground paddle;
wherein a distance between a distal end surface of the first vertical leg and a distal end surface of the second vertical leg is greater than a distance between a distal end surface of the first metal clip and a distal end surface of the second metal clip.

8. The semiconductor package of claim 2, wherein the first high side FET and the second high side FET are formed on a same semiconductor chip as common drain MOSFET.

9. The semiconductor package of claim 1, wherein the first low side FET is mounted on the first metal clip at a horizontal position shifted away from the first high side FET and the second low side FET is mounted on the second metal clip at a horizontal position shifted away from the second high side FET.

10. The semiconductor package of claim 1 further comprising a metal slug attached to the third metal clip;
wherein a top surface of the metal slug is exposed from the molding encapsulation.

11. A method for fabricating a semiconductor package, the method comprising the steps of:
providing a lead frame comprising
a die paddle,
a common ground paddle,
a first phase node lead, and
a second phase node lead;
mounting a first high side field-effect transistor (FET) and a second high side FET to the die paddle by a first solder layer,
the first high side FET comprising:
a source electrode and a gate electrode on a front surface of the first high side FET; and
a drain electrode on a back surface of the first high side FET;
the second high side FET comprising:
a source electrode and a gate electrode on a front surface of the second high side FET; and
a drain electrode on a back surface of the second high side FET;
attaching a first metal clip and a second metal clip to the first phase node lead and the second phase node lead respectively by a second solder layer,
the first metal clip connecting the source electrode of the first high side FET to the first phase node lead;
the second metal clip connecting the source electrode of the second high side FET to the second phase node lead;
mounting a first low side FET and a second low side FET to the first metal clip and the second metal clip respectively by a third solder layer,
the first low side FET comprising:
a source electrode and a gate electrode on a front surface of the first low side FET; and
a drain electrode on a back surface of the first low side FET;
the second low side FET comprising:
a source electrode and a gate electrode on a front surface of the second low side FET; and
a drain electrode on a back surface of the second low side FET;
attaching a third metal clip by a fourth solder layer, the third metal clip connecting the source electrode of the first low side FET and the source electrode of the second low side FET to the common ground paddle;
forming a molding encapsulation enclosing the first high side FET, the second high side FET, the first metal clip, the second metal clip, the first low side FET, the second low side FET, a majority portion of the lead frame, and at least a majority portion of the third metal clip; and
applying a singulation process separating the semiconductor package from adjacent semiconductor packages.

12. The method of claim 11, further comprising a step of attaching an integrated circuit (IC) to the third metal clip by a fifth solder layer after attaching the third metal clip.

13. The method of claim 12, further comprising a step of attaching a metal slug onto the third metal after attaching the third metal clip.

14. The method of claim 12, after the step of attaching the IC to the third metal clip, applying a wire bond process forming a plurality of bond wires.

15. The method of claim 12, after the step of attaching the third metal clip, attaching a metal slug to the third metal clip;
wherein a top surface of the metal slug is exposed from the molding encapsulation.

16. The method of claim 12, wherein the third metal clip comprises:
a lower portion and
an upper portion;
wherein a top surface of the upper portion of the third metal clip is exposed from the molding encapsulation.

17. The method of claim 12, wherein the semiconductor package excludes a metal slug; and
wherein the molding encapsulation encloses an entirety of the third metal clip.

18. The method of claim 12, wherein the third metal clip comprises:
a first vertical leg attached to the common ground paddle; and
a second vertical leg attached to the common ground paddle;
wherein a distance between a distal end surface of the first vertical leg and a distal end surface of the second vertical leg is greater than a distance between a distal end surface of the first metal clip and a distal end surface of the second metal clip.

19. The method of claim 12, wherein the semiconductor package is a dual driver metal-oxide-silicon field-effect transistor (DrMOSFET).

20. The method of claim 11, wherein the first high side FET and the second high side FET are formed on a same semiconductor chip as common drain MOSFET.
